(19) United States
(12) Patent Application Publication
(10) Pub. No.: US 2003/0080767 A1
(43) Pub. Date: May 1, 2003

(54) Method for checking integrated circuits

(76) Inventors: Tilmann Neunhoffer, Unterhaching (DE); Peter Baader, Munchen (DE); Claudia Thomas, Munchen (DE); Alexander Nielsen, Ingolstadt (DE)

Correspondence Address: LERNER AND GREENBERG, P.A., Post Office Box 2480, Hollywood, FL, 33022-2480, US

(21) Appl. No.: 10/284,779

(22) Filed: Oct. 31, 2002

(30) Foreign Application Priority Data
Oct. 31, 2001 (DE) 101 54 965.2
Nov. 30, 2001 (DE) 101 60 457.2

(51) Int. Cl. G01R 31/02

(52) U.S. Cl. 324/764

(57) ABSTRACT

A method for checking electrical networks, in which the geometric characteristics of all the components in the network are checked. Components that have predetermined geometric characteristics are marked. A test is then carried out to determine whether the marked components are disposed at required points in the network, that is to say whether they are interconnected as required. Conversely, it is also possible to check the interconnection of the components in the network, to mark the components with the required interconnection, and then to check whether they also have the required geometric characteristics.

### BACKGROUND OF THE INVENTION

### FIELD OF THE INVENTION

The invention relates in general and not exclusively to the automatic checking of the layout of integrated semiconductor circuits for the existence of and compliance of geometric rules for components which are characterized by their interconnection in a network list, by the combined use of a design rule check and a network list analysis.

When configuring the layout of integrated semiconductor circuits, it is generally necessary to comply with numerous geometric design rules. It is known for such design rules to be checked using suitable software by a so-called design rule check (DRC). Some of these rules need not be complied with throughout an entire chip, but only by specific components in the chip. Components such as these are generally characterized by their interconnection in the network list (that is to say the list of components provided in the chip).

On the other hand, it is necessary to ensure that certain required components with predetermined connections are actually present in the chip. For example, for protection against electric static discharges (ESD) in networks, two transistors which are connected respectively to power (VDD) and ground (VSS) as well as a diode (Type D) of appropriate size must be connected to input pads in order to make it possible to dissipate high voltages without damage to the chip. Furthermore, further transistors of special size and of the DiffPad type, and only these transistors, have to be connected by their drain to the input network. Further components are forbidden.

Similar rules also apply, for example, for protection against latch-up effects.

Compliance with the stated rules is normally generally checked by the use of specifically configured circuit and layout cells, which can be checked visually. Specific cells such as these are necessary since it is impossible to carry out a non-automated test of the entire chip. However, in some cases, a visual check is highly complex and is susceptible to errors. Some of the rules therefore cannot be tested at all on individual cells and, instead, the full chip must be tested, since the networks to be tested extend over a number of cells. Visual checking is therefore impossible for complex chips.

### SUMMARY OF THE INVENTION

It is accordingly an object of the invention to provide a method for checking integrated circuits that overcomes the above-mentioned disadvantages of the prior art methods of this general type, which allows automatic testing of the rules mentioned above.

With the foregoing and other objects in view there is provided, in accordance with the invention, a method for checking an electrical circuit having a number of networks and components. The method includes reading data extracted from a chip layout resulting in extracted data representing geometric characteristics of the components and of their interconnection to the networks, processing the extracted data to derive the geometric characteristics of the components, producing marked data for marking the extracted data representing the components having predetermined geometric characteristics, processing the marked data to check the interconnection of each of the components represented by the marked data for matching with at least one nominal interconnection, and producing a signal in dependence on a result of the check.

In one refinement, the method contains the following steps: processing of the extracted data in order to check the layout for compliance with predetermined geometric rules; and, in the event of noncompliance, with at least one of the predetermined rules, a second signal is produced in order to indicate the rule contravention. The check corresponds to the design rule check (DRC) as mentioned above. In this refinement, the DRC is carried out before the check of the interconnection of the extracted components. Alternatively, the DRC can be carried out after checking the interconnection of the extracted components.

In another refinement, a check of the geometric characteristics of the components that are interconnected in the network is carried out first. In this case, components that have predetermined geometric characteristics are marked. In order to mark the components they are, for example, written in a list or are provided with model names in the network list.

A network list analysis is then carried out in order to check whether the marked components are also actually disposed at the desired points within the network, that is to say whether they have a required interconnections. This process investigates what types of components are disposed at a large number of predetermined points to be investigated within the network. For this purpose, certain characteristics (for example geometric, electrical characteristics, connections) of the components disposed at the points are compared with nominal values. These nominal values are, for example, two transistors, which are respectively connected to power (VDD) and ground (VSS), at the input pads of a network for protection against ESD.

If the characteristics of a component that is disposed at a specific point correspond to the nominal values associated with this point, then it can be concluded that the required component is actually present at the investigated point. However, if the characteristics do not match the nominal values, then a component that does not belong there is disposed at the investigated point.

After the check, a first signal is produced and is emitted, containing information relating to the check and thus allowing correction, if necessary.

The method preferably has the following additional steps: reading of layout data which represents the layout of the circuit in a number of layers; processing of the layout data for detection of components (extraction); processing of the layout data in order to associate predetermined parameters with the detected components; and producing extracted data on the basis of the detected components and the associated parameters.

The detection of predetermined components is generally achieved by processing the data from a number of layers. The components to be taken into account in the present method have characteristic parameters in one or more of the layers, whose detection makes it possible to deduce the existence of a component which is associated with specific ones of these parameters. Each component detected in this way is then associated with (additional) parameters, which are then used to find out whether components that correspond to the requirements there are interconnected at predetermined points in the network.

The method advantageously has the additional step of producing an additional layer (marking layer) from the marked data. A further layer is then added to the various layers that describe the layout.

Subsequently, this allows easy access to the extracted components that have predetermined characteristics.

In one refinement, the data for marking extracted data contains model names, as a result of which each component that is represented by the marked data is associated with one of the model names, and with each model name is associated with a predetermined interconnection. The processing of the marked data for checking the interconnection of the components that are represented by the marked data contains the following substep: processing the marked data in order to compare the interconnection of those components that are represented by the marked data with the nominal interconnection of elements of the respectively associated model name.

The model names and the interconnection associated with each model name can be represented by appropriate data in a databank. The interconnections to be investigated can be checked easily by access to such a databank and to the respectively required data.

In another refinement, the method contains the following steps: processing the marked data in order to check the layout for compliance with predetermined geometric rules; and in the event of noncompliance with at least one of the predetermined rules, producing a second signal in order to indicate the rule contravention. In this refinement, the DRC is carried out after marking the components with a predetermined geometry, and preferably after production of the first signal. The DRC therefore has to be applied to only a reduced number of components.

In both refinements, a further signal is produced and emitted, so that a fault message can be indicated to a user (rule contravention DRC). The user can then take appropriate steps in order to correct the components and/or networks that caused the fault message.

The method can also be carried out for specific checking of a specific network within the circuit, or else on a large number of networks. It is thus possible to achieve a complete check of all the networks in a semiconductor circuit.

According to the invention, a method is furthermore created for checking an electrical circuit having a number of components and networks. The method includes receiving extracted data which represents geometric characteristics of the components and their interconnection to the networks; processing the extracted data in order to check the interconnection of the components; producing data for marking extracted data which represents components which have predetermined interconnections; processing the marked data in order to check the geometric characteristics of each of the components that are represented by the marked data for matching with the predetermined geometric characteristics; and producing a first signal as a function of the result of the check.

In addition, the method may contain the following step: producing a signal in order to indicate missing and/or superfluous components (network list analysis). The signal represents data that contains the result of the processing of the extracted data.

According to this method, the check is carried out in the opposite sequence to that in the first method according to the invention: the interconnection of the components to the networks is checked first. A check is then carried out to determine whether, on the basis of their interconnection, marked components are in compliance with the required geometric characteristics. In the first method, in contrast, those components were marked first of all which have the desired geometric characteristics (or are intended to have them if the DRC is carried out only at the end), after which a check is carried out to determine whether these components are located at suitable points, that is to say whether they are interconnected correctly.

The data for marking extracted data preferably likewise contains model names, by which each component that is represented by the marked data is associated with one of the model names, and with each model name being associated with predetermined nominal characteristics. The processing of the marked data for checking the geometric characteristics of the components that are represented by the marked data within the network containing the following substep of processing the marked data in order to compare the geometric characteristics of those components that are represented by the marked data with the geometric characteristics of the respectively associated model name.

The use of model names which each have specific associated geometric characteristics simplifies the processing of the marked data by making it possible to access a predetermined databank in which the necessary associations are stored.

In the event of noncompliance with at least one of the predetermined rules, a second signal is produced in order to indicate the rule contravention.

This check once again corresponds to the DRC mentioned above. The production of the second signal is intended to inform a user of the need for a correction. DRC is in this case advantageously carried out after the marking of the components with predetermined interconnections, so that the number of components that need to be taken into account in the DRC is less than the total number of components in the circuit to be investigated.

Once again, this method can also be carried out for specific checking of individual networks or a large number of networks in the circuit.

Furthermore, according to the invention, a computer program is provided for carrying out the method described above on a computer, as well as a computer having such a computer program implemented in it.

Other features which are considered as characteristic for the invention are set forth in the appended claims.

Although the invention is illustrated and described herein as embodied in a method for checking integrated circuits, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a circuit diagram of an example of an ESD protection structure for an input pad;

FIG. 2 is a flow chart showing a sequence of a method according to a first exemplary embodiment of the invention; and

FIG. 3 is a flow chart showing a sequence of the method according to a second exemplary embodiment of the invention.

### DESCRIPTION OF THE PREFERRED EMBODIMENTS

Software programs are known which can cover parts of a required test. These include the “Assura” program from Cadence Inc. for design rule checking (DRC) and extracting of a network list from a layout, and “HERC” from Infineon for network list analysis. A combination of these two programs allows implementation of a method according to the invention in accordance with the first exemplary embodiment.

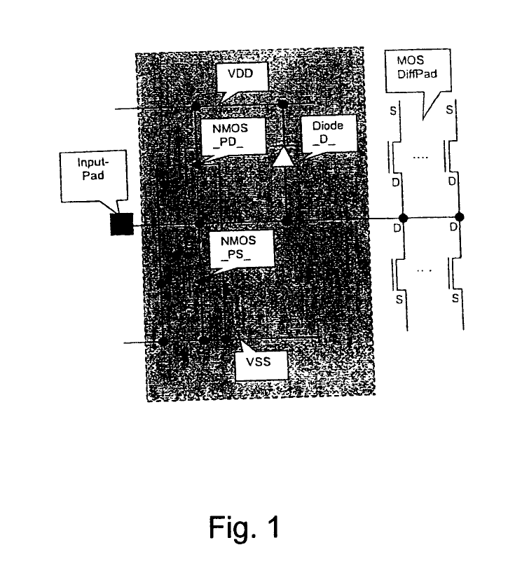

The invention will be described in the following text, by way of example using an ESD circuit shown in FIG. 1. However, in principle, the invention can also be used for any desired DRC and network list analysis tools and any desired combined geometry/network list oriented tests.

The interface between the DRC and the network list analysis consists in suitable marking of components. This may be done, for example, by using one of the two tools to enter specific components in a list, with the other tool having access to the list. Alternatively, specific components can be given their own model names, in order to identify them. The other tool can then evaluate the list or the model names, and take it or them into account in its tests.

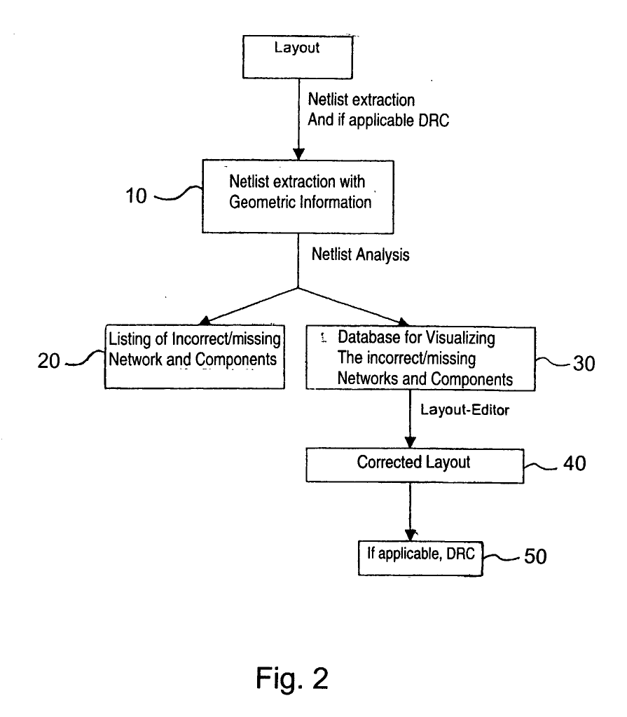

FIG. 2 shows a method according to a first exemplary embodiment of the invention. In this exemplary embodiment, network list extraction is carried out first, in order to extract components that satisfy the geometry-relevant part of the ESD rules, step 10. The components extracted in this way are then provided with suitable model names. Alternatively, the extracted components may just also be entered in a separate list.

The network list analysis is then carried out on the basis of the extracted network list. In the process, a check is carried out to determine whether the components identified in the first step are present. Networks with missing components or with components that are not marked or are incorrectly marked are written to a record of the network list analysis, step 20. A database displaying the missing components or with the components that are not marked or are incorrectly marked can be formed, step 30, and the corrections to the layout can then be made 40.

A DRC may be carried out either in parallel with the extraction or after the network list analysis, step 50.

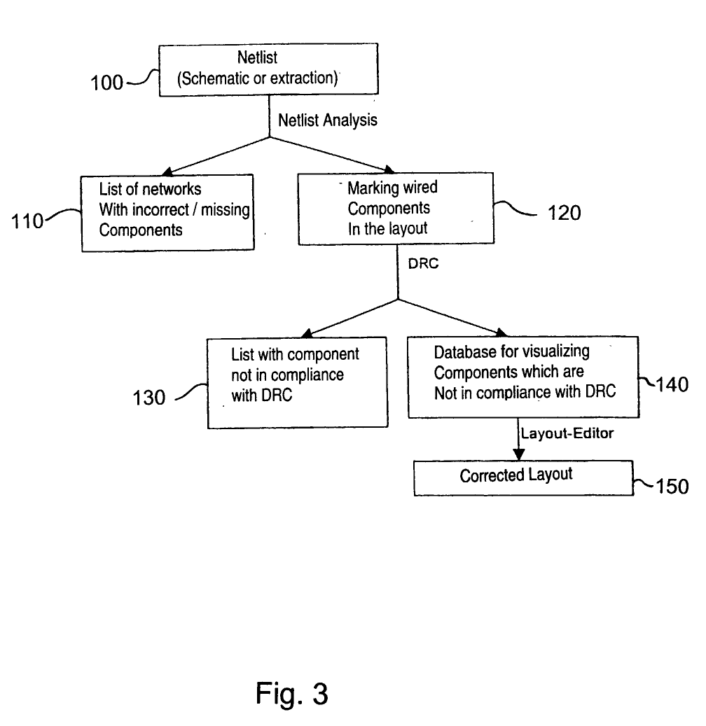

In a method according to a second exemplary embodiment of the invention, the network list analysis is first carried out. The sequence of the method according to the second exemplary embodiment is illustrated in FIG. 3. The network list analysis is in this case carried out on the basis of the schematic diagram or on the basis of an extracted network list from which “layout versus schematic” (LvS) has been removed, step 100; this should be regarded as including matching of a layout to a schematic on which the layout is based.

The network is first investigated to determine whether the required components are actually present with the required connections. Using the example of an input pad from FIG. 1, these would be two NMOS transistors NMOS_PD, NMOS_PS whose drains are connected to the pad network, whose gates and bulks are connected to VSS, and whose sources are connected respectively to VDD and VSS, as well as a diode D connected between the path network and VDD. If one of the components is missing, then a fault message is actually emitted during the network list analysis, step 110. If the components are interconnected correctly, then they are identified appropriately, step 120. This may be done by recording the components in a list, by allocation of model names, or by an additionally generated marking layer in the layout.

The marked components are then checked in the DRC for compliance with predetermined design rules. This sequence is illustrated in FIG. 3. However, with regard to the network illustrated in FIG. 1, it should be noted that, of course, not only the components mentioned in the last paragraph but all the components identified in the network list analysis are tested.

The result of this is that all the networks and/or components that do not satisfy the predetermined rules are entered in a record file, step 130. In addition, a database is produced, using which the faulty networks and components can be emphasized in a layout editor in the layout, step 140, and can then be corrected, step 150.

In comparison to visual checking of geometric characteristics of components at certain positions in a network list, this results in the following advantages:

a) a time savings;

b) flexibility in the formulation of the rules;

c) less susceptibility to errors during rule checking;

d) automatic recording;

e) simplified visualization of the problem points;

f) the automatic rule check can also be carried out by “non-experts” in the field of the rules to be satisfied; and

g) this results in greater robustness of the semiconductor circuits, for example in the event of ESD and latch-up effects.

In general, in summary, it can be stated that the combination of DRC and network list analysis makes it possible in a reliable manner to check components which are characterized by particular interconnections in the network list for compliance with specific geometric rules. In the process, components with special interconnections are marked in the network list analysis, after which the geometric rules for the marked components are checked in the DRC. Alternatively, the geometric rules can be checked first in the DRC and in the extraction. All the components that comply with the geometric rules are marked during the extraction. An investigation is then carried out in the network list analysis to determine whether components with markings are disposed at the required points.

This may be used in particular for the checking of ESD rules, since these rules are becoming evermore important as structures become increasingly smaller and use new technologies.

It should be noted that the invention is not restricted to the described exemplary embodiments, but covers modifications within the area of protection defined by the claims.

We claim:

1. A method for checking an electrical circuit having a number of networks and components, which comprises the steps of:
reading data extracted from a chip layout resulting in extracted data representing geometric characteristics of the components and of their interconnection to the networks;
processing the extracted data to derive the geometric characteristics of the components;
producing marked data for marking the extracted data representing the components having predetermined geometric characteristics;
processing the marked data to check the interconnection of each of the components represented by the marked data for matching with at least one nominal interconnection; and
producing a signal in dependence on a result of the check.

2. The method according to claim 1, which comprises generating the signal to contain information indicating that the interconnection of none of the components represented by the marked data matches at least one nominal interconnection.

3. The method according to claim 1, which comprises generating the signal to contain information representing the components that are represented by the marked data whose interconnection does not match at least one nominal interconnection.

4. The method according to claim 1, which comprises:
processing unmarked data to check the interconnection of the components represented by the unmarked data for matching with at least one nominal interconnection; and
producing a further signal in dependence on a result of the check of the unmarked data.

5. The method according to claim 4, which comprises generating the further signal to contain information about any match between at least one of the components represented by the unmarked data and at least one nominal interconnection.

6. The method according to claim 5, which comprises generating the further signal to contain further information representing the components that are represented by the unmarked data whose interconnection matches at least one nominal interconnection.

7. The method according to claim 1, which comprises:
reading layout data representing the chip layout of the electrical circuit in a number of layers;
processing the layout data for detecting the components;
processing the layout data to associate predetermined parameters with the-components detected; and
producing the extracted data on a basis of the components detected and the associated predetermined parameters.

8. The method according to claim 7, which comprises producing an additional layer from the marked data.

9. The method according to claim 1, wherein the data contains model names for marking the extracted data, by which each of the components represented by the marked data is associated with one of the model names, a predetermined interconnection being associated with each of the model names, and the processing of the marked data for checking the interconnection of the components represented by the marked data contains the following substep:
processing the marked data to compare the interconnection of the components that are represented by the marked data with a nominal interconnection of elements of a respectively associated model name.

10. The method according to claim 1, which comprises generating the marked data to contain a list of the components represented by the marked data.

11. The method according to claim 4, which comprises:
processing the extracted data to check the electrical circuit for compliance with predetermined geometric rules (DRC); and
producing an additional signal to indicate a rule contravention in an event of noncompliance with at least one of the predetermined geometric rules.

12. The method according to claim 4, which comprises:
processing the marked data to check the chip layout for compliance with predetermined geometric rules (DRC); and
producing an additional signal to indicate a rule contravention in an event of noncompliance with at least one of the predetermined geometric rules.

13. The method according to claim 12, wherein the processing of the marked data for checking the chip layout for compliance with the predetermined geometric rules (DRC) step and the producing of the additional signal step are carried out after the production of the signal.

14. The method according to claim 11, which comprises:
repeating the steps for checking a number of the networks in the electrical circuit; and
producing a given signal in dependence on the checking of the number of networks.

15. The method according to claim 14, which comprises generating the given signal to contain information indicating that the interconnection of the components that are represented by the marked data does not match at least one nominal interconnection in at least one of the networks.

16. The method according to claim 14, which comprises generating the given signal to contain information identifying the networks in which the interconnection of the components that are represented by the marked data does not match at least one nominal interconnection.

17. A method for checking an electrical circuit having a number of networks and components, which comprises the steps of:
receiving extracted data representing geometric characteristics of the components and their interconnection to the networks;
processing the extracted data to derive the interconnection of the components;
producing data for marking the extracted data representing the components having one of a number of predetermined interconnections resulting in marked data;
processing the marked data for checking the geometric characteristics of each of the components represented by the marked data for matching with predetermined geometric characteristics; and
producing a signal in dependence on a result of the checking step.

18. The method according to claim 17, which comprises generating a given signal to indicate at least one of missing and superfluous components.

19. The method according to claim 17, which comprises generating the signal to contain information indicating that the geometric characteristics of none of the components represented by the marked data match the predetermined geometric characteristics.

20. The method according to claim 17, which comprises generating the signal to contain information representing the components that are represented by the marked data having the geometric characteristics that do not match the predetermined geometric characteristics.

21. The method according to claim 17, which comprises:
receiving layout data representing a layout of the networks in a number of layers;
processing the layout data to detect predetermined components;
processing the layout data to associate predetermined interconnection parameters with the components detected; and
producing the extracted data on a basis of the components detected and the predetermined interconnection parameters.

22. The method according to claim 21, which comprises producing an additional layer from the marked data.

23. The method according to claim 17, wherein the data for marking the extracted data contains model names, by which each of the components represented by the marked data is associated with one of the model names, each of the model names being associated with predetermined nominal characteristics, and the processing of the marked data for checking the geometric characteristics of the components represented by the marked data within a network contains the following substep:
processing the marked data to compare the geometric characteristics of the components represented by the marked data with the geometric characteristics of a respectively associated model name.

24. The method according to claim 17, which comprises generating the marked data to contain a list of the components having one of the predetermined interconnections.

25. The method according to claim 17, which comprises:
processing the marked data to check if a layout is in compliance with predetermined geometric rules (DRC); and
producing a further signal to indicate a rule contravention in an event of noncompliance with at least one of the predetermined rules.

26. The method according to claim 17, which comprises:
repeating the steps for checking a number of the networks in the electrical circuit; and
producing an additional signal in dependence on results of the checking of the number of networks.

27. The method according to claim 26, wherein the additional signal contains information indicating that, in at least one of the networks checked, the geometric characteristics of none of the components represented by the marked data match the predetermined geometric characteristics.

28. The method according to claim 26, which comprises generating the additional third signal to contain information identifying the networks in which the geometric characteristics of none of the components represented by the marked data match the predetermined geometric characteristics.

29. A computer program, comprising:
computer executable instructions for carry out the method according to claim 1.

30. A computer, comprising:
a computer program having executable instructions according to claim 1.
